(19) United States
(12) Patent Application Publication
(10) Pub. No.: US 2008/0081463 A1
(43) Pub. Date: Apr. 3, 2008

(54) Method for fabricating storage node contact in semiconductor device

(75) Inventor: Jun-Hyeub Sun, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/823,778

(22) Filed: Jun. 28, 2007

(30) Foreign Application Priority Data
Sep. 28, 2006 (KR) 2006-0095196

(51) Int. Cl. H01L 21/4763

(52) U.S. Cl. 438/637; 257/E21.495

(57) ABSTRACT

A method for forming a storage node contact in a semiconductor device includes forming a first insulation layer over a substrate including a landing plug, forming bit lines over the first insulation layer, each bit line including a bit line tungsten layer and a bit line hard mask, forming a second insulation layer over the first insulation layer, etching a portion of the second insulation layer to form a first open region, enlarging a width of the first open region, etching the remaining second insulation layer and the first insulation layer to form a second open region exposing a surface of the landing plug, forming spacers over sidewalls of a storage node contact hole including the first and second open regions, the spacers including an oxide-based layer and a nitride-based layer, and filling the storage node contact hole with a conductive material to form a storage node contact.

### CROSS-REFERENCE TO RELATED APPLICATIONS

The present invention claims priority of Korean patent application number 10-2006-0095196, filed on Sep. 28, 2006, which is incorporated by reference in its entirety.

### BACKGROUND OF THE INVENTION

The present invention relates to a method for fabricating a semiconductor device, and more particularly, to a method for forming a storage node contact using a line type self-aligned contact etch.

As semiconductor devices become highly integrated, a contact has been formed as a trench type using an argon fluoride (ArF) photoresist in a storage node contact plug of 80 nm technology or smaller.

However, when a storage node contact (SNC1) is formed in a trench type, an exposed surface area of an upper portion of the storage node contact is small because a storage node contact plug is filled in a trench type storage node contact hole. Thus, a lack of overlay margin with a subsequent storage node results. Therefore, a pad polysilicon (SNC2) is generally required to be formed in-between.

Furthermore, the ArF photoresist used when performing an etch process to form the trench type storage node contact hole causes an increased maintenance cost due to the application of expensive apparatuses. Thus, mass producibility is diminished. A method for forming a line type storage node contact has been introduced to overcome aforementioned limitations.

FIGS. 1A to 1E illustrate cross-sectional views of a typical method for forming a storage node contact in a semiconductor device.

Referring to FIG. 1A, gate patterns G are formed over a semi-finished substrate 11. Each gate pattern G includes a gate insulation layer 12, a gate conductive layer 13, and a gate hard mask 14. Gate spacers 15 are formed on sidewalls of the gate patterns G. A first insulation layer 16 is formed over the substrate structure. Landing plugs 17 are formed in the first insulation layer 16 and coupled to the substrate 11. A second insulation layer 18 is formed over the first insulation layer 16. Bit lines BL are formed over certain portions of the second insulation layer 18. Each bit line BL includes a stack structure configured with a bit line tungsten layer 19 and a bit line hard mask 20. Bit line spacers 21 are formed on sidewalls of the bit lines BL. A third insulation layer 22 is formed over the second insulation layer 18 and the bit lines BL. Hard masks 23 are formed over the third insulation layer 22. The hard masks 23 include polysilicon layers. The hard masks 23 are formed in a line type structure.

Referring to FIG. 1B, a portion of the third insulation layer 22 is etched to form an open region using the hard masks 23 as an etch barrier. At this time, the open region is formed to a depth which does not expose the bit line tungsten layers 19. A wet etch process is performed to enlarge a line width of the open region. Thus, a first open region 24 is formed. Reference numeral 22A refers to an etched third insulation layer 22A.

Referring to FIG. 1C, a nitride-based layer 25 for forming a spacer is formed over the surface profile of the hard masks 23 and the first open region 24.

Referring to FIG. 1D, the nitride-based layer 25 is etched using a dry etch process. Thus, storage node contact spacers 25A are formed over upper portions of the bit line hard masks 20. A bottom portion of the first open region 24 is etched until the landing plug 17 is exposed to form a second open region 26. Reference numerals 22B and 18A refer to a third insulation pattern 22B and a second insulation pattern 18A, respectively.

Referring to FIG. 1E, a conductive layer, e.g., a polysilicon layer, for forming a plug is formed over the substrate structure and filled in a storage node contact hole configured with the first open region 24 and the second open region 26. A planarization process, e.g., a chemical mechanical polish (CMP) process, is performed to form a storage node contact plug 27. The hard masks 23 are removed during the planarization process.

It is possible to pattern with a krypton fluoride (KrF) photoresist when the line type storage node contact hole is applied. However, it may be difficult to obtain a self-aligned contact margin characteristic because the bit line hard masks 20 of the bit lines BL are exposed while forming the line type storage node contact hole, resulting in a large etch loss of the bit line hard masks 20. It may be difficult to secure a self-aligned contact margin in a device of 60 nm technology or less even if a nitride-based layer is formed as the storage node contact spacers 25A.

### SUMMARY OF THE INVENTION

Embodiments of the present invention are directed to provide a method for forming a storage node contact in a semiconductor device, which can secure a self-aligned contact margin and reduce an etch loss of a bit line hard mask when forming a line type storage node contact hole.

In accordance with an aspect of the present invention, there is provided a method for forming a storage node contact in a semiconductor device, including: forming a first insulation layer over a semi-finished substrate including a landing plug; forming bit lines over the first insulation layer, each bit line including a stack structure comprising a bit line tungsten layer and a bit line hard mask; forming a second insulation layer over the first insulation layer to insulate the adjacent bit lines; etching a portion of the second insulation layer to form a first open region in a manner that the bit line tungsten layers are not exposed; enlarging a width of the first open region; etching the remaining second insulation layer and the first insulation layer to form a second open region exposing a surface of the landing plug; forming spacers over sidewalls of a storage node contact hole including the first and second open regions, the spacers including a stack structure comprising an oxide-based layer and a nitride-based layer; and filling the storage node contact hole with a conductive material to form a storage node contact.

In accordance with another aspect of the present invention, there is provided a method for forming a storage node contact in a semiconductor device, including: forming a first insulation layer over a semi-finished substrate; forming bit lines including a tungsten layer over the first insulation layer, each bit line including a stack structure; forming a second insulation layer over the first insulation layer to insulate the adjacent bit lines; etching a portion of the second insulation layer to form a first open region in a manner that the bit line tungsten layers are not exposed; enlarging a width of the first open region; etching a remaining portion of the second insulation layer and the first insulation layer to form a second open region; forming spacers over sidewalls of a storage node contact hole including the first and second open regions; and filling the storage node contact hole with a conductive material to form a storage node contact.

### BRIEF DESCRIPTION OF THE DRAWINGS

FIGS. 1A to 1E illustrate cross-sectional views of a typical method for forming a storage node contact in a semiconductor device.

FIGS. 2A to 2F illustrate cross-sectional views of a method for forming a storage node contact in a semiconductor device in accordance with an embodiment of the present invention.

FIG. 3 illustrates a diagram showing a self-aligned contact of storage node contact holes and storage node contact plugs.

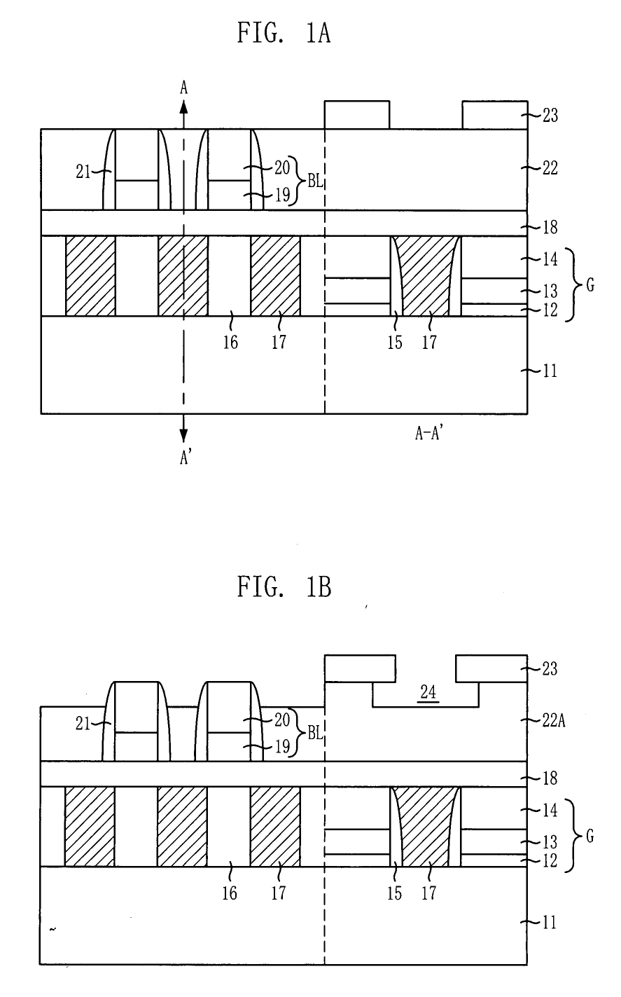

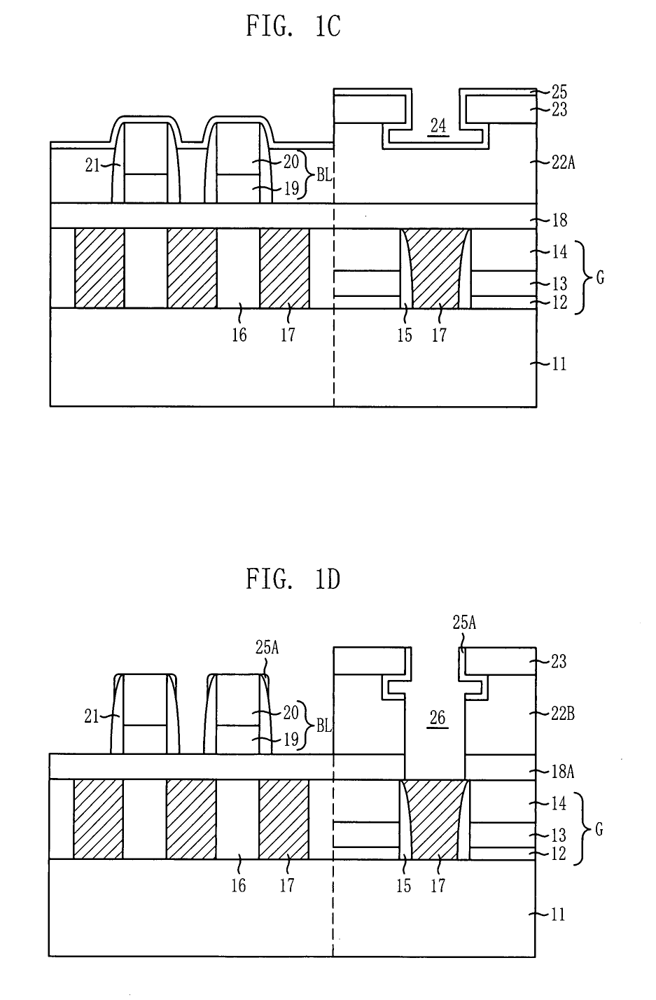

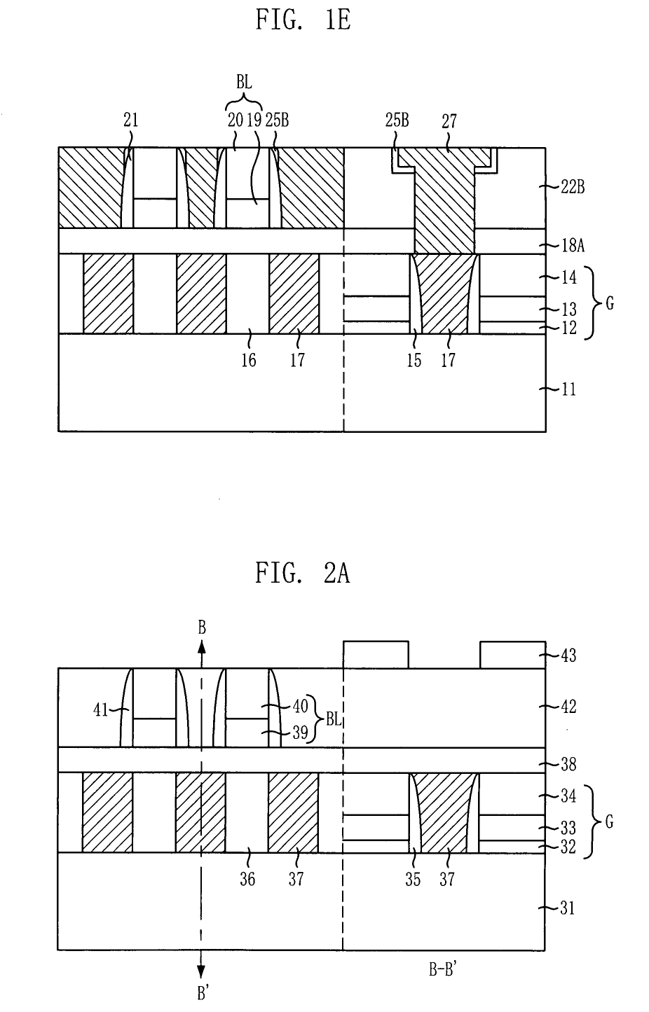

### DESCRIPTION OF SPECIFIC EMBODIMENTS

Embodiments of the present invention relate to a method for fabricating a storage node contact in a semiconductor device.

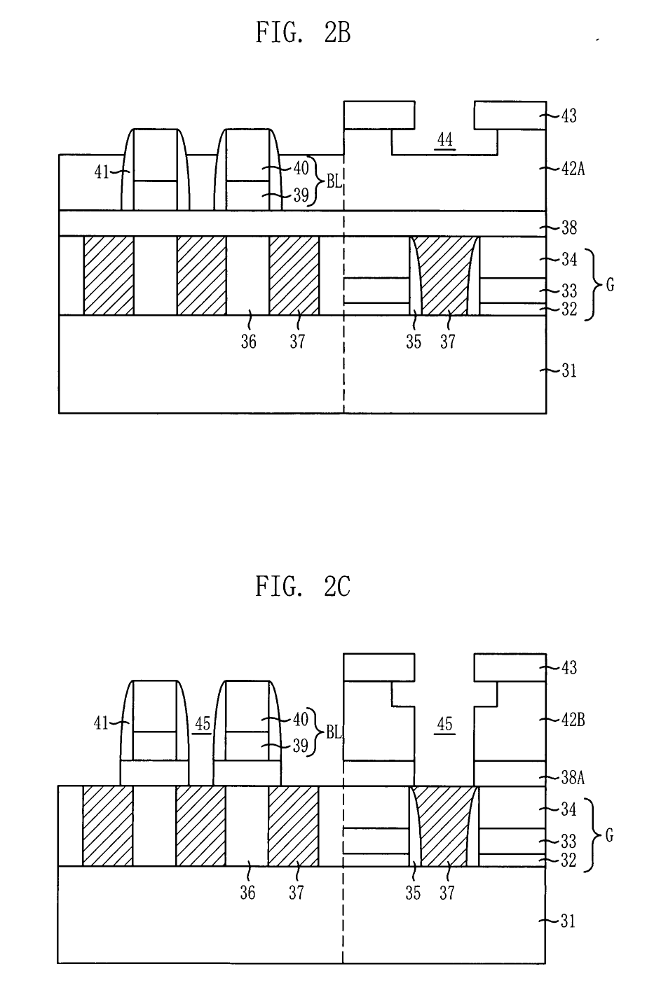

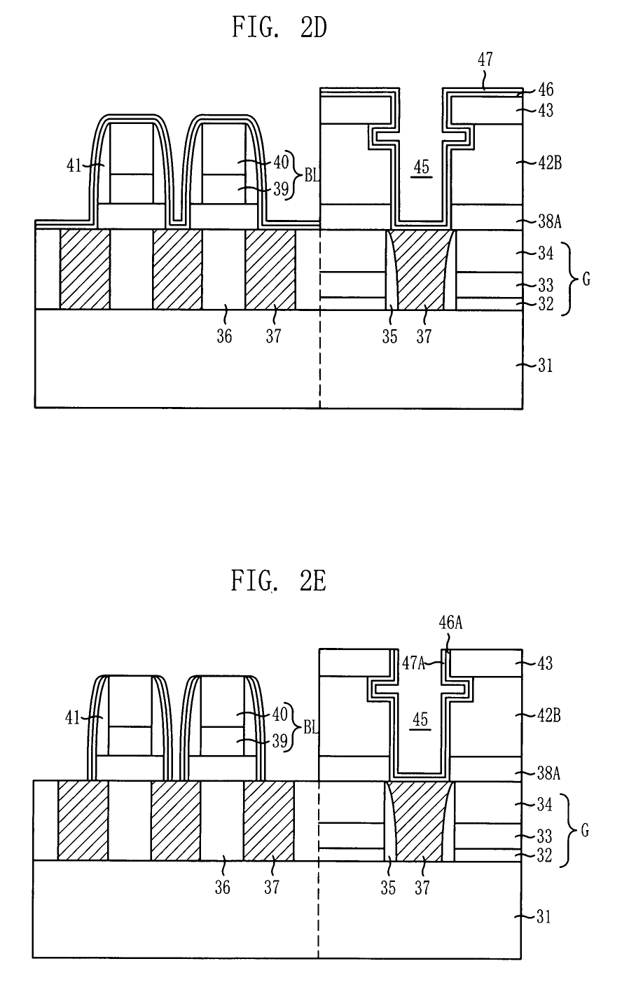

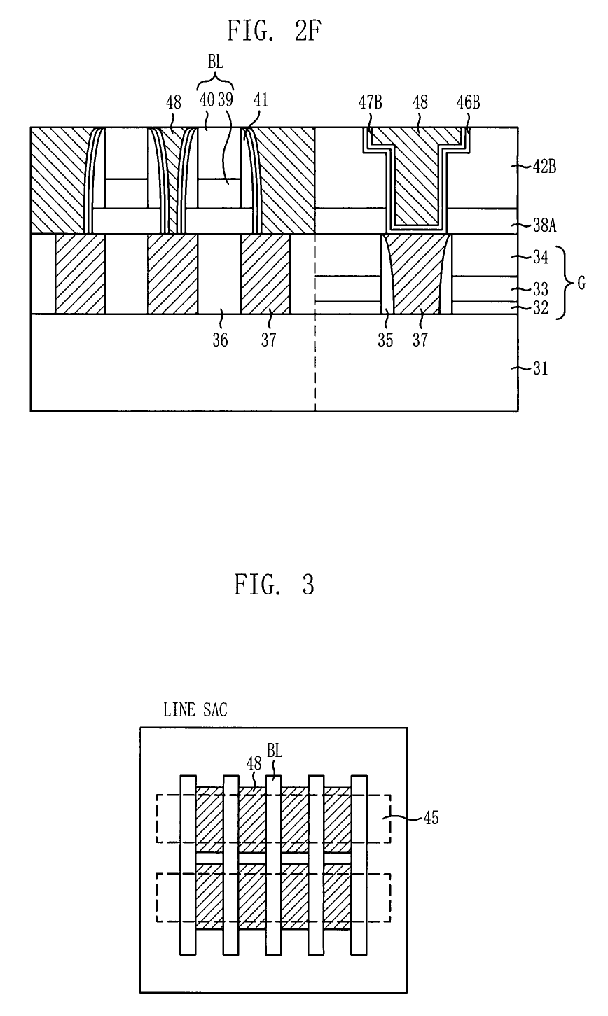

FIGS. 2A to 2F illustrate cross-sectional views of a method for forming a storage node contact in a semiconductor device in accordance with an embodiment of the present invention.

Referring to FIG. 2A, gate patterns G are formed over a semi-finished substrate 31. Generally required processes for forming a dynamic random access memory (DRAM) such as a well process and an isolation structure process are performed on the substrate 31 in advance. Each gate pattern G includes a gate insulation layer 32, a gate conductive layer 33, and a gate hard mask 34. The gate insulation layers 32 are typically formed using a thermal oxidation process or a dry/wet oxidation process. The gate conductive layers 33 include a polysilicon layer, a metal layer, or a metal silicide layer. The gate hard masks 34 include a silicon nitride (Si₃N₄) layer.

Gate spacers 35 are formed on sidewalls of the gate patterns G. A first insulation pattern 36 including landing plugs 37 is formed over the substrate 31 and the gate patterns G. In more detail, a first insulation layer is formed over the gate patterns G and the substrate 31. A planarizing process is performed until the gate hard masks 34 are exposed. The landing plugs 37 are then formed in the first insulation layer, coupled to the substrate 31. The landing plugs 37 include polysilicon plugs.

A second insulation layer 38 is formed over the first insulation pattern 36. Bit lines BL are formed over certain portions of the second insulation layer 38. Each bit line BL includes a stack structure configured with a bit line tungsten layer 39 and a bit line hard mask 40. Bit line spacers 41 are formed on sidewalls of the bit lines BL. The bit line spacers 41 have an increased thickness when compared to typical bit line spacers. The bit line spacers 41 may be formed to a thickness ranging from approximately 200 Å to approximately 300 Å. For instance, the typical bit line spacers are formed to a thickness of approximately 130 Å, whereas the bit line spacers 41 according to the embodiment of the present invention are formed to a thickness of approximately 260 Å. Thus, the increased thickness of the bit line spacers 41 improves a self-aligned contact (SAC) margin. Meanwhile, the bit line spacers 41 include a nitride-based layer.

A third insulation layer 42 is formed over the bit lines BL and the second insulation layer 38. Hard masks 43 are formed over the third insulation layer 42. The hard masks 43 include a polysilicon layer. The hard masks 43 are formed in a line type structure.

Referring to FIG. 2B, a portion of the third insulation layer 42 is etched to form an open region using the hard masks 43 as an etch barrier. The open region is formed by performing a dry etch process on the third insulation layer 42 using the hard masks 43 as an etch barrier to form a depression. A wet etch process is then performed on the depression to enlarge a line width of the open region. Thus, a first open region 44 is formed. Reference numeral 42A refers to an etched third insulation layer 42A. Enlarging the line width of the open region causes an upper surface area of a subsequent storage node contact to increase. Thus, an overlap margin with a storage node may be secured.

The wet etch process has an isotropic characteristic. Thus, sidewalls and a bottom surface of the depression are etched in all directions to substantially the same depth. The wet etch process uses a chemical that is typically used to etch an insulation layer. The first open region 44 is formed to an intended depth which does not expose the bit line tungsten layers 39.

Referring to FIG. 2C, portions of the etched third insulation layer 42A and the second insulation layer 38 below the first open region 44 are dry etched using the hard masks 43 as an etch barrier. Reference numerals 42B and 38A refer to a third insulation pattern 42B and a second insulation pattern 38A, respectively. Thus, second open regions exposing an upper portion of the landing plugs 37 are formed. Therefore, storage node contact holes 45 including the first open region 44 and the second open regions are formed. Formation of the storage node contact holes 45 includes forming the second open regions without forming a storage node contact spacer after the first open region 44 is formed, unlike a typical method. Thus, an exposed surface area of the storage node contact holes 45 is maximized, and an open margin may be secured in a device of 60 nm technology or less.

Referring to FIG. 2D, an oxide-based layer 46 for forming a spacer and a nitride-based layer 47 for forming a spacer are formed over the surface profile of the hard masks 43 and the storage node contact holes 45. The oxide-based layer 46 is formed to a thickness ranging from approximately 450 Å to approximately 550 Å and the nitride-based layer 47 is formed to a thickness ranging from approximately 100 Å to approximately 200 Å. When the oxide-based layer 46 includes a undoped silicate glass (USG) layer having a deteriorated step coverage characteristic, a thickness of a portion of the USG layer formed over an upper portion of the bit line hard masks 40 is larger than other portions of the USG layer formed over sidewalls and bottom surfaces of the substrate structure. Thus, the SAC margin may be further improved.

Referring to FIG. 2E, a dry etch process is performed on the nitride-based layer 47 and the oxide-based layer 46 to form storage node contact spacers. The storage node contact spacers each include a patterned oxide-based layer 46A and a patterned nitride-based layer 47A.

Referring to FIG. 2F, a polysilicon layer for forming a plug is filled in the storage node contact holes 45 to form storage node contact plugs 48.

FIG. 3 illustrates a diagram showing a SAC of storage node contact holes and storage node contact plugs. The storage node contact holes 45 are self-aligned between the bit lines BL, and the line type storage node contact plugs 48 are self-aligned by the storage node contact holes 45.

In accordance with the embodiment of the present invention, the line type storage node contact plugs are formed using the KrF photoresist. The bit line spacers are formed thicker than those used in the typical method to reduce the etch loss which generally occurs due to exposure of bit line hard masks. Thus, a SAC margin may be further secured.

A line width is enlarged after a partial etching is performed and then spacers are formed during a typical storage node contact hole formation. In contrast, the storage node contact holes are formed right after the partial etching and the enlargement of the line width according to the embodiment of the present invention. Thus, a spacer surface area may be secured. Also, since the stack structure including the oxide-based layer and the nitride-based layer is used as the storage node contact spacers, the capacitance of the bit lines may be reduced as well as improving the SAC margin.

In accordance with the embodiment of the present invention, the line type storage node contact holes are formed using the KrF as a photo-exposure source. Thus, a typical second storage node contact formation process using ArF as a photo-exposure source may be omitted. Furthermore, omitting the second storage node contact formation process results in a reduced fabrication cost due to a reduced number of total processes.

While the present invention has been described with respect to the specific embodiments, it will be apparent to those skilled in the art that various changes and modifications may be made without departing from the spirit and scope of the invention as defined in the following claims.

What is claimed is:

1. A method for forming a storage node contact in a semiconductor device, the method comprising:
forming a first insulation layer over a semi-finished substrate including a landing plug;
forming bit lines over the first insulation layer, each bit line including a stack structure comprising a bit line tungsten layer and a bit line hard mask;
forming a second insulation layer over the first insulation layer to insulate the adjacent bit lines;
etching a portion of the second insulation layer to form a first open region in a manner that the bit line tungsten layers are not exposed;
enlarging a width of the first open region;
etching the remaining second insulation layer and the first insulation layer to form a second open region exposing a surface of the landing plug;
forming spacers over sidewalls of a storage node contact hole including the first and second open regions, the spacers including a stack structure comprising an oxide-based layer and a nitride-based layer; and
filling the storage node contact hole with a conductive material to form a storage node contact.

2. The method of claim 1, wherein forming the spacers comprises:
forming the oxide-based layer and the nitride-based layer over a surface profile of a substrate structure; and
performing a dry etch process.

3. The method of claim 2, wherein the oxide-based layer comprises an undoped silicate glass (USG) layer.

4. The method of claim 3, wherein a portion of the oxide-based layer is formed over an upper portion of the bit lines and has a larger thickness than other portions of the oxide-based layer formed over the sidewalls of the bit lines and bottom surfaces between the bit lines.

5. The method of claim 2, wherein the oxide-based layer is formed to a thickness ranging from approximately 450 Å to approximately 550 Å and the nitride-based layer is formed to a thickness ranging from approximately 100 Å to approximately 200 Å.

6. The method of claim 1, wherein the bit lines include bit line spacers formed on sidewalls of the bit lines, the bit line spacers formed to a thickness ranging from approximately 200 Å to approximately 300 Å.

7. The method of claim 1, wherein the storage node contact is formed in a line type structure.

8. The method of claim 1, wherein the storage node contact hole is formed using krypton fluoride (KrF) as a photo-exposure source.

9. The method of claim 1, wherein forming the second insulation layer over the first insulation layer to insulate the adjacent bit lines comprises planarizing the second insulation layer until the bit line hard masks of the bit lines are exposed.

10. A method for forming a storage node contact in a semiconductor device, the method comprising:
forming a first insulation layer over a semi-finished substrate;
forming bit lines including a tungsten layer over the first insulation layer, each bit line including a stack structure;
forming a second insulation layer over the first insulation layer to insulate the adjacent bit lines;
etching a portion of the second insulation layer to form a first open region in a manner that the bit line tungsten layers are not exposed;
enlarging a width of the first open region;
etching a remaining portion of the second insulation layer and the first insulation layer to form a second open region;
forming spacers over sidewalls of a storage node contact hole including the first and second open regions; and
filling the storage node contact hole with a conductive material to form a storage node contact.

11. The method of claim 10, wherein the semi-finished substrate includes a landing plug and the stack structure includes a bit line hard mask.

12. The method of claim 11, wherein etching of the remaining portion exposes a surface of the landing plug.

13. The method of claim 10, wherein the spacers include a stack structure comprising an oxide-based layer and a nitride-based layer.
